(19) United States
(12) Patent Application Publication
(10) Pub. No.: US 2026/0188195 A1
(43) Pub. Date: Jul. 2, 2026

(54) PIXEL CIRCUIT, DISPLAY DEVICE AND ELECTRONIC DEVICE

(71) Applicant: Samsung Display Co., Ltd., Yongin-si (KR)

(72) Inventors: Jongwoo Jin, Yongin-si (KR); TETSUHIRO TANAKA, Yongin-si (KR)

(21) Appl. No.: 19/406,677

(22) Filed: Dec. 2, 2025

(30) Foreign Application Priority Data
Jan. 2, 2025 (KR) 10-2025-0000244

(51) Int. Cl. G09G 3/32

(52) U.S. Cl. CPC G09G 3/32; G09G 2330/021

(57) ABSTRACT

A pixel circuit includes a light-emitting element connected between a first power line and a second power line, a first driving transistor connected between the first power line and the light-emitting element, and including a source terminal and a drain terminal, and a second driving transistor connected between the first power line and the light-emitting element, and including a source terminal connected to the source terminal of the first driving transistor, and a drain terminal connected to the drain terminal of the first driving transistor, wherein, based on a display mode, either only the first driving transistor is driven, or both the first driving transistor and the second driving transistor are driven together.

### CROSS-REFERENCE TO RELATED APPLICATION

The present application claims priority to, and the benefit of, Korean Patent Application No. 10-2025-0000244, filed on Jan. 2, 2025, in the Korean Intellectual Property Office, the entire disclosure of which is incorporated herein by reference.

### BACKGROUND

### 1. Field

The present disclosure relates to a pixel circuit, a display device and an electronic device.

### 2. Description of the Related Art

A pixel emits light based on a data voltage, and includes a transistor (e.g., a thin-film transistor (TFT)) that controls the operation of the pixel. A display device may display images in a sequential emission manner, in which pixels emit light sequentially in rows, or in a concurrent/substantially simultaneous emission manner, in which all pixels emit light substantially simultaneously after data writing is completed sequentially.

### SUMMARY

An aspect of the present disclosure provides a pixel circuit, a display device including the same, and an electronic device including the same. Aspects provided by the present disclosure are not limited to the aspects mentioned above, and other aspects of the present disclosure that are not mentioned may be understood by the following description and will be more clearly understood through the embodiments of the present disclosure. In addition, it will be appreciated that the present disclosure may be realized by the means defined in the appended claims and combinations of the means.

One or more embodiments of the present disclosure disclose a pixel circuit including a light-emitting element connected between a first power line and a second power line, a first driving transistor connected between the first power line and the light-emitting element, and including a source terminal and a drain terminal, and a second driving transistor connected between the first power line and the light-emitting element, and including a source terminal connected to the source terminal of the first driving transistor, and a drain terminal connected to the drain terminal of the first driving transistor, wherein, based on a display mode, either only the first driving transistor is driven, or both the first driving transistor and the second driving transistor are driven together.

The pixel circuit may further include a switching circuit configured to either turn off the second driving transistor, or connect a gate terminal of the second driving transistor to a gate terminal of the first driving transistor, based on the display mode.

The switching circuit may include a first switching transistor connected between the gate terminal of the first driving transistor and the gate terminal of the second driving transistor, and a second switching transistor connected between an off-voltage line and the gate terminal of the second driving transistor.

The drain terminal of the first driving transistor and the drain terminal of the second driving transistor may be connected to an anode of the light-emitting element.

The pixel circuit may further include a storage capacitor having a first terminal connected to a gate terminal of the first driving transistor, and a second terminal connected to the first power line, and a scan transistor connected between a data line and the gate terminal of the first driving transistor, and configured to be turned on in response to a scan signal.

The pixel circuit may further include a substrate, a first active pattern above the substrate, and extending in a first direction on a plane, a second active pattern above the substrate, and extending in the first direction on the plane, and an upper gate pattern, wherein the first driving transistor includes the first active pattern, and a first portion of the upper gate pattern overlapping the first active pattern, and wherein the second driving transistor includes the second active pattern, and a second portion of the upper gate pattern overlapping the second active pattern.

A length of the first active pattern in the first direction may be different from a length of the second active pattern in the first direction.

A width of the first active pattern in a second direction crossing the first direction may be different from a width of the second active pattern in the second direction.

One or more embodiments of the present disclosure disclose a pixel circuit including a light-emitting element connected between a first power line and a second power line, a first driving transistor connected between the first power line and the light-emitting element, and including a source terminal, and a second driving transistor connected between the first power line and the light-emitting element, and including a drain terminal connected to the source terminal of the first driving transistor, wherein, based on a display mode, either only the first driving transistor is driven, or both the first driving transistor and the second driving transistor are driven together.

The pixel circuit may further include a switching circuit configured to either connect a gate terminal of the first driving transistor to a gate terminal of the second driving transistor, or turn on the second driving transistor, based on the display mode.

The switching circuit may include a first switching transistor connected between the gate terminal of the first driving transistor and the gate terminal of the second driving transistor, and a second switching transistor connected between an on-voltage line and the gate terminal of the second driving transistor.

The drain terminal of the second driving transistor may be connected to an anode of the light-emitting element.

The pixel circuit may further include a storage capacitor having a first terminal connected to a gate terminal of the first driving transistor, and a second terminal connected to the first power line, and a scan transistor connected between a data line and the gate terminal of the first driving transistor, and configured to be turned on in response to a scan signal.

The pixel circuit may further include a substrate, a first active pattern above the substrate, and extending in a first direction on a plane, a second active pattern above the substrate, and extending in the first direction on the plane, and an upper gate pattern, wherein the first driving transistor includes the first active pattern, and a first portion of the upper gate pattern overlapping the first active pattern, and wherein the second driving transistor includes the second active pattern, and a second portion of the upper gate pattern overlapping the second active pattern.

A length of the first active pattern in the first direction may be different from a length of the second active pattern in the first direction.

A width of the first active pattern in a second direction crossing the first direction may be different from a width of the second active pattern in the second direction.

One or more embodiments of the present disclosure disclose an electronic device including a memory, a processor configured to execute an application stored in the memory, and a display module configured to process a signal transmitted from the processor, and to output image information, the display module including pixel circuits, the pixel circuits including a light-emitting element connected between a first power line and a second power line, and a driving transistor connected between the first power line and the light-emitting element, including a first gate terminal and a second gate terminal, and configured to be controlled to have a source-sync structure or a gate-sync structure based on a display mode.

The pixel circuit may further include a switching circuit configured to control the second gate terminal of the driving transistor to be connected to the first gate terminal of the driving transistor, or to control the second gate terminal of the driving transistor to be connected to a source terminal of the driving transistor, based on the display mode.

The switching circuit may include a first switching transistor connected between the first gate terminal of the driving transistor and the second gate terminal of the driving transistor, and a second switching transistor connected between the second gate terminal of the driving transistor and the source terminal of the driving transistor.

The pixel circuit may further include a substrate, an active pattern above the substrate, and extending in a first direction on a plane, a buffer layer between the substrate and the active pattern, an upper gate pattern above the active pattern, and a lower gate pattern between the substrate and the buffer layer, and wherein the driving transistor includes the active pattern, a portion of the upper gate pattern overlapping the active pattern, and a portion of the lower gate pattern overlapping the active pattern.

Aspects other than those described above will become apparent from the following drawings, claims and detailed description.

### BRIEF DESCRIPTION OF THE DRAWINGS

These and/or other aspects will become apparent and more readily appreciated from the following description of the embodiments, taken in conjunction with the accompanying drawings in which:

FIG. 1 is a block diagram illustrating a display device according to one or more embodiments of the present disclosure;

FIG. 2 is a circuit diagram showing a pixel circuit according to one or more embodiments of the present disclosure;

FIG. 3 is a circuit diagram of a switching circuit according to one or more embodiments of the present disclosure;

FIG. 4 is a circuit diagram showing a pixel circuit according to one or more other embodiments of the present disclosure;

FIG. 5 is a circuit diagram of a switching circuit according to one or more other embodiments of the present disclosure;

FIG. 6 is a circuit diagram showing a pixel circuit according to one or more other embodiments of the present disclosure;

FIG. 7 is a circuit diagram of a switching circuit according to one or more other embodiments of the present disclosure;

FIG. 8 is a cross-sectional view showing a portion of a pixel circuit, according to one or more embodiments;

FIG. 9 is a cross-sectional view showing a portion of a pixel circuit according to one or more other embodiments;

FIG. 10 is a plan view showing a display area according to one or more embodiments;

FIG. 11 is a plan view showing a display area according to one or more embodiments;

FIG. 12 is a block diagram of an electronic device according to one or more embodiments; and

FIG. 13 is a schematic diagram of electronic devices according to various embodiments.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing an embodiment corresponds to one or more embodiments of the present disclosure.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

In the drawings, the relative sizes of elements, layers, and regions may be exaggerated for clarity and/or descriptive purposes. In other words, because the sizes and thicknesses of elements in the drawings are arbitrarily illustrated for convenience of description, the disclosure is not limited thereto. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Spatially relative terms, such as “beneath,” “below,” “lower,” “lower side,” “under,” “above,” “upper,” “over,” “higher,” “upper side,” “side” (e.g., as in “sidewall”), and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component (e.g., an apparatus, a device, a circuit, a wire, an electrode, a terminal, a conductive film, etc.) is referred to as being “formed on,” “on,” “connected to,” or “(operatively, functionally, or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a transistor, a resistor, an inductor, a capacitor, a diode and/or the like. Accordingly, a connection is not limited to the connections illustrated in the drawings or the detailed description and may also include other types of connections. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components, such as “between,” “immediately between” or “adjacent to” and “directly adjacent to,” may be construed similarly. It will be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XY, YZ, and XZ, or any variation thereof. Similarly, the expressions “at least one of A and B” and “at least one of A or B” may include A, B, or A and B. As used herein, “or” generally means “and/or,” and the term “and/or” includes any and all combinations of one or more of the associated listed items. For example, the expression “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list. When “C to D” is stated, it means C or more and D or less, unless otherwise specified.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are only used to distinguish one element, member, component, region, area, layer, section, or portion from another element, member, component, region, area, layer, section, or portion. Thus, a first element, component, region, layer, or section described below could be termed a second element, component, region, layer, or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

When one or more embodiments may be implemented differently, a specific process order may be performed differently from the described order. For example, two consecutively described processes may be performed substantially at the same time or performed in an order opposite to the described order.

As used herein, the terms “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/−5 % of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.” Furthermore, the expression “being the same” may mean “being substantially the same.” In other words, the expression “being the same” may include a range that can be tolerated by those of ordinary skill in the art. The other expressions may also be expressions from which “substantially” has been omitted.

In some embodiments well-known structures and devices may be described in the accompanying drawings in relation to one or more functional blocks (e.g., block diagrams), units, and/or modules to avoid unnecessarily obscuring various embodiments. Those skilled in the art will understand that such block, unit, and/or module are/is physically implemented by a logic circuit, an individual component, a microprocessor, a hard wire circuit, a memory element, a line connection, and other electronic circuits. This may be formed using a semiconductor-based manufacturing technique or other manufacturing techniques. The block, unit, and/or module implemented by a microprocessor or other similar hardware may be programmed and controlled using software to perform various functions discussed herein, optionally may be driven by firmware and/or software. In addition, each block, unit, and/or module may be implemented by dedicated hardware, or a combination of dedicated hardware that performs some functions and a processor (for example, one or more programmed microprocessors and related circuits) that performs a function different from those of the dedicated hardware. In addition, in some embodiments, the block, unit, and/or module may be physically separated into two or more interact individual blocks, units, and/or modules without departing from the scope of the present disclosure. In addition, in some embodiments, the block, unit and/or module may be physically combined into more complex blocks, units, and/or modules without departing from the scope of the present disclosure.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

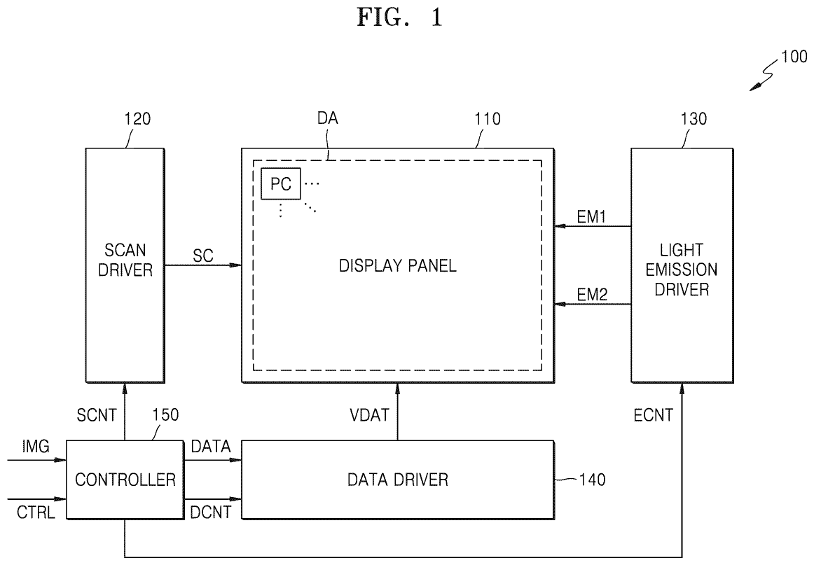

FIG. 1 is a block diagram illustrating a display device according to one or more embodiments of the present disclosure.

Referring to FIG. 1, a display device 100 may include a display panel 110 and a panel driver (e.g., a panel-driving unit). The display panel 110 may include a plurality of pixel circuits PC arranged in a display area DA. The display area DA may correspond to an area in which an image is displayed on the display panel 110.

The panel driver may drive the display panel 110. The panel driver may include a scan driver 120, a light emission driver 130, a data driver 140, and a controller 150.

The scan driver 120 may provide scan signals SC to the pixel circuits PC. The scan driver 120 may generate scan signals SC based on a scan control signal SCNT. The scan control signal SCNT may include a scan start signal, a scan clock signal, etc.

The light emission driver 130 may provide one or more light emission signals (e.g., a first light emission signal EM1 and a second light emission signal EM2) to the pixel circuits PC. The light emission driver 130 may generate one or more light emission signals based on a light emission control signal ECNT. The light emission control signal ECNT may include an emission start signal, an emission clock signal, etc.

The data driver 140 may provide data voltages VDAT to the pixel circuits PC. The data driver 140 may generate the data voltages VDAT based on a data signal DATA and a data control signal DCNT. The data driver 140 may convert a digital data signal DATA into analog data voltages VDAT. The data control signal DCNT may include a load signal, a data clock signal, etc.

The controller 150 may control the operation of the scan driver 120, the operation of the light emission driver 130, and the operation of the data driver 140. The controller 150 may provide the scan control signal SCNT to the scan driver 120, the light emission control signal ECNT to the light emission driver 130, and the data signal DATA and the data control signal DCNT to the data driver 140. The controller 150 may generate the scan control signal SCNT, the light emission control signal ECNT, the data signal DATA, and the data control signal DCNT, based on image data IMG and a controller control signal CTRL. The controller 150 may convert the image data IMG into the data signal DATA. The controller control signal CTRL may include a master clock signal, a vertical sync signal, a horizontal sync signal, a data enable signal, etc.

A pixel including a pixel circuit PC or the display device 100 may control a method of driving a light-emitting element, based on a display mode set in the display device 100.

In the present disclosure, the display mode may be any one of a first operation mode, which is a standard mode as a normal operation mode, a second operation mode for fine grayscale representation in a low-grayscale area, and a third operation mode for efficiently generating output in a high-grayscale area. For example, the second operation mode may correspond to a case where the display device 100 is in a dark environment, and the third operation mode may correspond to a case where the display device 100 is under sunlight.

In the present disclosure, the display device 100 may adjust or change a transistor, which drives a light-emitting element, or the connection relationship of transistors, according to the display mode.

Various embodiments for implementing the display device 100 of the present disclosure will be described below.

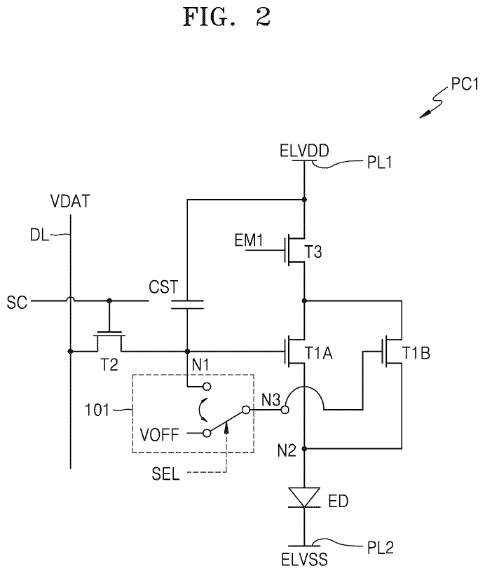

FIG. 2 is a circuit diagram showing a pixel circuit according to one or more embodiments of the present disclosure.

The pixel circuit PC1 of FIG. 2 may correspond to at least some of the pixel circuits PC of the display device 100 of FIG. 1.

In the pixel circuit PC1 of FIG. 2, based on the display mode, either only the first driving transistor may be driven, or both the first driving transistor and the second driving transistor may be driven together.

Referring to FIG. 2, the pixel circuit PC1 may include a light-emitting element ED, a first driving transistor T1A, a second driving transistor T1B, a storage capacitor CST, a scan transistor T2, and a light-emission control transistor T3.

The light-emitting element ED may be connected between a first power line PL1 and a second power line PL2. The first power line PL1 may transmit a first power supply voltage ELVDD, and the second power line PL2 may transmit a second power supply voltage ELVSS. The level of the first power supply voltage ELVDD may be higher than the level of the second power supply voltage ELVSS.

The light-emitting element ED may include an anode connected to a second node N2, and a cathode connected to the second power line PL2. The light-emitting element ED may emit light with luminance corresponding to radiative current flowing in the light-emitting element ED. In one or more embodiments, the light-emitting element ED may include an organic light-emitting diode, an inorganic light-emitting diode, a micro light-emitting diode, or a quantum-dot light-emitting diode.

The first driving transistor T1A may be connected between the first power line PL1 and the light-emitting element ED. The second driving transistor T1B may be connected between the first power line PL1 and the light-emitting element ED (e.g., the first and second riving transistors T1A and T1B may be connected in parallel).

Each of the first and second driving transistors T1A and T1B may include one gate. In other words, each of the first and second driving transistors T1A and T1B may have a single-gate structure.

The first driving transistor T1A may include a gate terminal connected to a first node N1, a drain terminal connected to a source terminal of the light-emission control transistor T3, and a source terminal connected to the second node N2. The second driving transistor T1B may include a gate terminal connected to a third node N3, a drain terminal connected to the source of the light-emission control transistor T3, and a source terminal connected to the second node N2.

The storage capacitor CST may include a first terminal connected to the first node N1 and a second terminal connected to the first power line PL1.

The scan transistor T2 may be connected between a data line DL and the first node N1, and may be turned on in response to the scan signal SC. The scan transistor T2 may include a gate terminal for receiving the scan signal SC, a drain terminal connected to the data line DL, and a source terminal connected to the first node N1.

The light-emission control transistor T3 may be turned on in response to the first light emission signal EM1. The light-emission control transistor T3 may include a gate terminal for receiving the first light emission signal EM1, a drain terminal connected to the first power line PL1, and a source terminal connected to the drain terminal of the first driving transistor T1A and to the drain terminal of the second driving transistor T1B.

Radiative current flowing in the light-emitting element ED may corresponding to a first driving current flowing in the first driving transistor T1A, or the sum of the first driving current and a second driving current flowing in the second driving transistor T1B.

In one or more embodiments, the driving range of the first driving transistor T1A may be wider than the driving range of the second driving transistor T1B. The driving range of a transistor may refer to a range of the gate-to-source voltage of the transistor, which corresponds to a given range of current flowing in the transistor (e.g., about 10 pA to about 10 nA). When the driving range of a driving transistor is wide, current flowing in the driving transistor may be finely controlled. Accordingly, the luminance of light emitted by a light-emitting element may also be finely controlled.

The on-current of the second driving transistor T1B may be greater than the on-current of the first driving transistor T1A. The on-current of a transistor may refer to current that flows in the transistor when a gate-on voltage is applied to the gate of the transistor. Even if the same data voltage is applied to the gate of a driving transistor, a larger current may flow in the driving transistor when the on-current of the driving transistor is large, and accordingly, the power consumption of the pixel circuit PC1 may be reduced.

The gate terminal of the first driving transistor T1A and the gate terminal of the second driving transistor T1B may be connected to a switching circuit 101. The switching circuit 101 may switch the connection relationship of the circuit, based on a selection signal SEL. The selection signal SEL may be generated and applied according to the display mode.

The switching circuit 101 of the pixel circuit PC1 may control the gate terminal of the second driving transistor T1B to be connected to the gate terminal of the first driving transistor T1A, or may control the second driving transistor T1B to be turned off by applying an off-voltage VOFF to the gate terminal of the second driving transistor T1B.

For example, the switching circuit 101 may control the off-voltage VOFF to be applied to the third node N3 (e.g., to the gate terminal of the second driving transistor T1B) when the selection signal SEL has a low voltage. Accordingly, the second driving transistor T1B may not operate, and only the first driving transistor T1A may be used as a transistor that drives the light-emitting element ED.

Contrarily, the switching circuit 101 may control the third node N3 (e.g., the gate terminal of the second driving transistor T1B) to be connected to the first node N1 (e.g., to the gate terminal of the first driving transistor T1A) when the selection signal SEL has a high voltage. Accordingly, both the first driving transistor T1A and the second driving transistor T1B may be used to drive the light-emitting element ED.

In the above, the case where the selection signal SEL has a low voltage may correspond to the first operation mode or to the second operation mode. In other words, for the fine grayscale representation in the normal operation mode or in the low-grayscale area, only the first driving transistor T1A having a wide driving range may be used. Contrarily, the case where the selection signal SEL has a high voltage may correspond to the third operation mode. In other words, because the fine grayscale representation is not required, the second driving transistor T1B having high on-current may also be used for power efficiency.

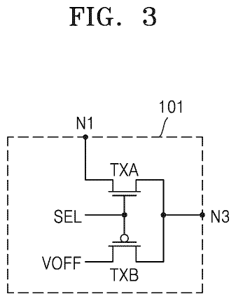

FIG. 3 is a circuit diagram of a switching circuit according to one or more embodiments of the present disclosure.

The switching circuit 101 of FIG. 3 may be an example of the switching circuit 101 included in the pixel circuit PC1 of FIG. 2.

The switching circuit 101 may include a first switching transistor TXA and a second switching transistor TXB. The first switching transistor TXA may be an n-type transistor, and the second switching transistor TXB may be a p-type transistor. When the selection signal SEL has a low voltage, the first switching transistor TXA may be turned off and the second switching transistor TXB may be turned on. When the selection signal SEL has a high voltage, the first switching transistor TXA may be turned on and the second switching transistor TXB may be turned off.

The first switching transistor TXA may be connected between the first node N1 and the third node N3. When the first switching transistor TXA is turned on, the first node N1 and the third node N3 may be electrically connected to each other.

The second switching transistor TXB may be connected between the third node N3 and an off-voltage line to which the off-voltage VOFF is applied. When the second switching transistor TXB is turned on, the off-voltage VOFF may be applied to the third node N3.

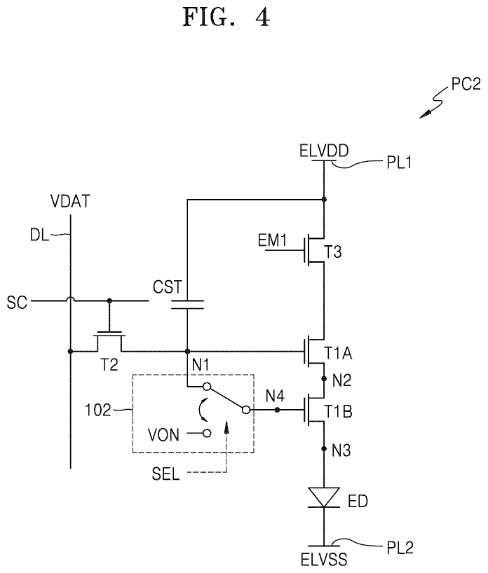

FIG. 4 is a circuit diagram showing a pixel circuit according to one or more other embodiments of the present disclosure.

The pixel circuit PC2 of FIG. 4 may correspond to at least some of the pixel circuits PC of the display device 100 of FIG. 1.

Repeated detailed description of the configurations in FIG. 4 that are identical to the configurations in FIG. 2 will be omitted.

Referring to FIG. 4, the pixel circuit PC2 may include a light-emitting element ED, a first driving transistor T1A, a second driving transistor T1B, a storage capacitor CST, a scan transistor T2, and a light-emission control transistor T3.

The light-emitting element ED may be connected between a first power line PL1 and a second power line PL2.

The light-emitting element ED may include an anode connected to a third node N3, and a cathode connected to the second power line PL2.

The first driving transistor T1A may include a gate terminal connected to a first node N1, a drain terminal connected to a source terminal of the light-emission control transistor T3, and a source terminal connected to the second node N2. The second driving transistor T1B may include a gate terminal connected to a fourth node N4, a drain terminal connected to the second node N2, and a source terminal connected to the third node N3.

The gate terminal of the first driving transistor T1A and the gate terminal of the second driving transistor T1B may be connected to a switching circuit 102. The switching circuit 102 may switch the connection relationship of the circuit based on a selection signal SEL. The selection signal SEL may be generated and applied according to the display mode.

The switching circuit 102 of the pixel circuit PC2 may control the gate terminal of the second driving transistor T1B to be connected to the first driving transistor T1A, or may control an on-voltage VON to be applied to the gate terminal of the second driving transistor T1B.

For example, the switching circuit 102 may control the fourth node N4 (e.g., the gate terminal of the second driving transistor T1B) to be connected to the first node N1 (e.g., the gate terminal of the first driving transistor T1A) when the selection signal SEL has a high voltage. Accordingly, the first driving transistor T1A and the second driving transistor T1B may be connected in series to each other.

Contrarily, the switching circuit 102 may control the on-voltage VON to be applied to the fourth node N4 (e.g., the gate terminal of the second driving transistor T1B) when the selection signal SEL has a low voltage. Accordingly, the second driving transistor T1B may be turned on regardless of the operation of the first driving transistor T1A.

In the above, the case where the selection signal SEL has a high voltage may correspond to the first operation mode or to the second operation mode. In other words, for the fine grayscale representation in the normal operation mode or the low-grayscale area, the first driving transistor T1A and the second driving transistor T1B may be connected in series to each other, so that the length of a transistor is increased, and so that the driving range is widened.

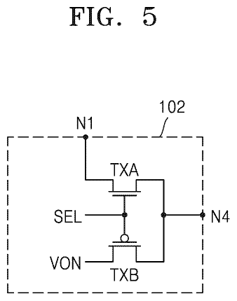

FIG. 5 is a circuit diagram of a switching circuit according to one or more other embodiments of the present disclosure.

The switching circuit 102 of FIG. 5 may be an example of the switching circuit 102 included in the pixel circuit PC2 of FIG. 4.

The switching circuit 102 may include a first switching transistor TXA and a second switching transistor TXB. The first switching transistor TXA may be an n-type transistor, and the second switching transistor TXB can be a p-type transistor. When the selection signal SEL has a low voltage, the first switching transistor TXA may be turned off and the second switching transistor TXB may be turned on. When the selection signal SEL has a high voltage, the first switching transistor TXA may be turned on and the second switching transistor TXB may be turned off.

The first switching transistor TXA may be connected between the first node N1 and the fourth node N4. When the first switching transistor TXA is turned on, the first node N1 and the fourth node N4 may be electrically connected to each other.

The second switching transistor TXB may be connected between the fourth node N4 and an on-voltage line to which the on-voltage VON is applied. When the second switching transistor TXB is turned on, the on-voltage VON may be applied to the fourth node N4.

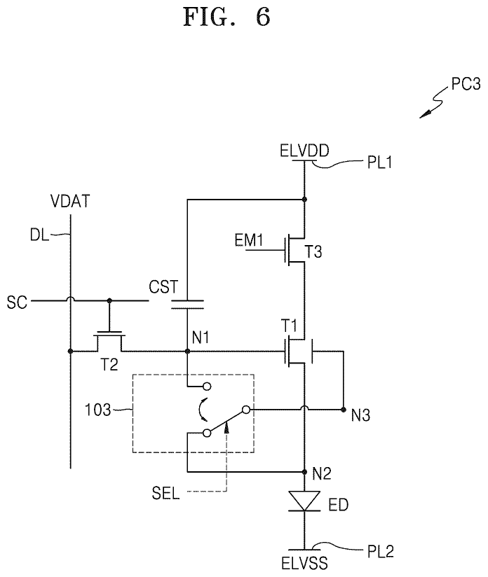

FIG. 6 is a circuit diagram showing a pixel circuit according to one or more other embodiments of the present disclosure.

The pixel circuit PC3 of FIG. 6 may correspond to at least some of the pixel circuits PC of the display device 100 of FIG. 1.

Repeated detailed description of the configurations in FIG. 6 that are identical to the configurations in FIG. 2 will be omitted.

Referring to FIG. 6, the pixel circuit PC3 may include a light-emitting element ED, a driving transistor T1, a storage capacitor CST, a scan transistor T2, and a light-emission control transistor T3.

The light-emitting element ED may be connected between a first power line PL1 and a second power line PL2.

The light-emitting element ED may include an anode connected to a second node N3, and a cathode connected to the second power line PL2.

The driving transistor T1 of the pixel circuit PC3 may include two gate terminals. The driving transistor T1 may include a first gate terminal connected to a first node N1, a second gate terminal connected to the third node N3, a drain terminal connected to a source terminal of the light-emission control transistor T3, and a source terminal connected to the second node N2.

The first gate terminal of the driving transistor T1, the second gate terminal of the driving transistor T1, and the source terminal of the driving transistor T1 may be connected to a switching circuit 103. The switching circuit 103 may switch the connection relationship of the pixel circuit PC3, based on a selection signal SEL. The selection signal SEL may be generated and applied according to the display mode.

The switching circuit 103 of the pixel circuit PC3 may control the second gate terminal of the driving transistor T1 to be connected to either the first gate terminal of the driving transistor T1 or to the source terminal of the driving transistor T1.

For example, the switching circuit 103 may control the third node N3 (e.g., the second gate terminal of the driving transistor T1) to be connected to the source terminal of the driving transistor T1 when the selection signal SEL has a low voltage. Accordingly, the driving transistor T1 may have a source-sync structure.

Contrarily, the switching circuit 103 may control the fourth node N4 (e.g., the second gate terminal of the driving transistor T1) to be connected to the first gate terminal of the driving transistor T1 when the selection signal SEL has a high voltage. Accordingly, the driving transistor T1 may have a gate-sync structure.

In the above, the case where the selection signal SEL has a low voltage may correspond to the first operation mode or to the second operation mode. In other words, for the fine grayscale representation in the normal operation mode or the low-grayscale area, the driving transistor T1 having a source-sink structure with a wide driving range may be used. Contrarily, the case where the selection signal SEL has a high voltage may correspond to the third operation mode. In other words, if the fine grayscale representation is not required, the driving transistor T1 having a gate-sink structure having a low on-current may be used for power efficiency.

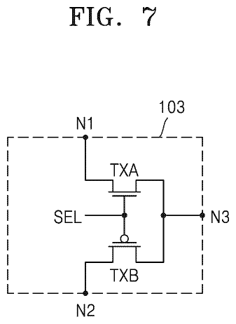

FIG. 7 is a circuit diagram of a switching circuit according to one or more other embodiments of the present disclosure.

The switching circuit 103 of FIG. 7 may be an example of the switching circuit 103 included in the pixel circuit PC3 of FIG. 6.

The switching circuit 103 may include a first switching transistor TXA and a second switching transistor TXB. The first switching transistor TXA may be an n-type transistor, and the second switching transistor TXB may be a p-type transistor. When the selection signal SEL has a low voltage, the first switching transistor TXA may be turned off and the second switching transistor TXB may be turned on. When the selection signal SEL has a high voltage, the first switching transistor TXA may be turned on and the second switching transistor TXB may be turned off.

The first switching transistor TXA may be connected between the first node N1 and the third node N3. When the first switching transistor TXA is turned on, the first node N1 and the third node N3 may be electrically connected to each other.

The second switching transistor TXB may be connected between the second node N2 and the third node N3. When the second switching transistor TXB is turned on, the second node N2 and the third node N3 may be electrically connected to each other.

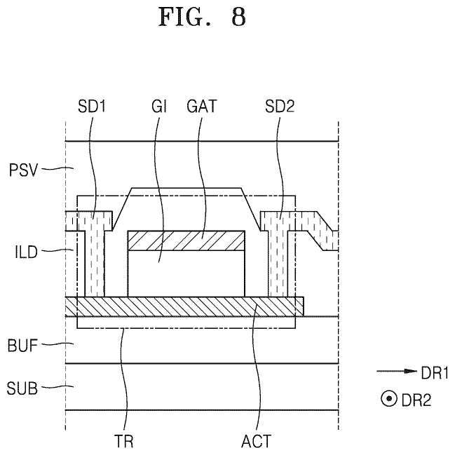

FIG. 8 is a cross-sectional view showing a portion of a pixel circuit according to one or more embodiments.

In FIG. 8, the transistor (TR) may correspond to a portion forming at least some of the transistors in accordance with aforementioned embodiments. For example, the pixel circuit of FIG. 8 may correspond to the pixel circuit PC1 according to one or more embodiments corresponding to FIG. 2 or to the pixel circuit PC2 according to one or more embodiments corresponding to FIG. 4.

The pixel circuit may include a substrate SUB, a buffer layer BUF, an active pattern ACT, a gate-insulating layer GI, an upper gate pattern GAT, an interlayer insulating layer ILD, a first conductive pattern SD1, a second conductive pattern SD2, and a protective layer PSV.

The substrate SUB may include glass, plastic, or the like.

The buffer layer BUF may be arranged on the substrate SUB. The buffer layer BUF may include an inorganic insulating material, such as silicon nitride, silicon oxide, or the like.

The active pattern ACT may be arranged on the buffer layer BUF. The active pattern ACT may extend in a first direction DR1 on a plane. The active pattern ACT may include a semiconductor material, such as an oxide semiconductor.

The upper gate pattern GAT may be arranged on the active pattern ACT. The upper gate pattern GAT may include a metal, such as molybdenum (Mo), titanium (Ti), or the like.

The gate-insulating layer GI may be between the active pattern ACT and the upper gate pattern GAT. The gate-insulating layer GI may include an inorganic insulating material, such as silicon nitride, silicon oxide, or the like.

The interlayer insulating layer ILD may be arranged on the active pattern ACT and the upper gate pattern GAT. The interlayer insulating layer ILD may include an inorganic insulating material, such as silicon nitride, silicon oxide, or the like.

The first conductive pattern SD1 and the second conductive pattern SD2 may be arranged on the interlayer insulating layer ILD. The first conductive pattern SD1 and the second conductive pattern SD2 may include a metal, such as aluminum (Al), titanium (Ti), or the like.

The protective layer PSV may be arranged on the first conductive pattern SD1 and the second conductive pattern SD2. The protective layer PSV may include an inorganic insulating material, such as silicon nitride, silicon oxide, or the like, and/or an organic insulating material such as polyimide.

A driving transistor of a pixel circuit may include the active pattern ACT, and a portion of the upper gate pattern GAT (an upper gate), which overlaps the active pattern ACT.

When the pixel circuit includes two types of driving transistors (e.g., a first driving transistor and a second driving transistor), the first driving transistor may include a first active pattern and a first portion (e.g., a first upper gate or a first upper gate portion) of the upper gate pattern GAT overlaps the first active pattern, and the second driving transistor may include a second active pattern and a second portion (e.g., a second upper gate or a second upper gate portion) of the upper gate pattern GAT overlapping the second active pattern. The first active pattern and the second active pattern may be arranged in the same layer.

When the pixel circuit PC1 described with reference to FIG. 2 or the pixel circuit PC2 described with reference to FIG. 4 has the structure illustrated in FIG. 8, the first driving transistor T1A of FIG. 2 or 4 may have a different structure, component, characteristic, or the like than the second driving transistor T1B of FIG. 2 or 4.

For example, the length in the first direction DR1 of the first active pattern (e.g., the active pattern ACT corresponding to the first driving transistor T1A) may be greater than the length in the first direction DR1 of the second active pattern (e.g., the active pattern ACT corresponding to the second driving transistor T1B). In this case, the driving range of the first driving transistor T1A may be wider than the driving range of the second driving transistor T1B.

For example, the width in a second direction DR2 of the first active pattern (e.g., the active pattern ACT corresponding to the first driving transistor T1A) may be less than the width in the second direction DR2 of the second active pattern (e.g., the active pattern ACT corresponding to the second driving transistor T1B), wherein the second direction DR2 crosses the first direction DR1. In this case, the driving range of the first driving transistor T1A may be wider than the driving range of the second driving transistor T1B.

The semiconductor material of the active pattern ACT corresponding to the first driving transistor T1A may be different from the semiconductor material of the active pattern ACT corresponding to the second driving transistor T1B. For example, the active pattern ACT corresponding to the first driving transistor T1A may include indium gallium zinc oxide (IGZO), and the active pattern ACT corresponding to the second driving transistor T1B may include an oxide semiconductor having a higher mobility than IGZO. In this case, the on-current of the second driving transistor T1B may be greater than the on-current of the first driving transistor T1A including the active pattern ACT.

The thickness of the gate-insulating layer GI between the upper gate pattern GAT and the active pattern ACT corresponding to the first driving transistor T1A may be different from the thickness of the gate-insulating layer GI between the upper gate pattern GAT and the active pattern ACT corresponding to the second driving transistor T1B. For example, the thickness of the gate-insulating layer GI between the upper gate pattern GAT and the active pattern ACT corresponding to the first driving transistor T1A may be greater than the thickness of the gate-insulating layer GI between the upper gate pattern GAT and the active pattern ACT corresponding to the second driving transistor T1B. The driving range of the first driving transistor T1A may be wider than the driving range of the second driving transistor T1B.

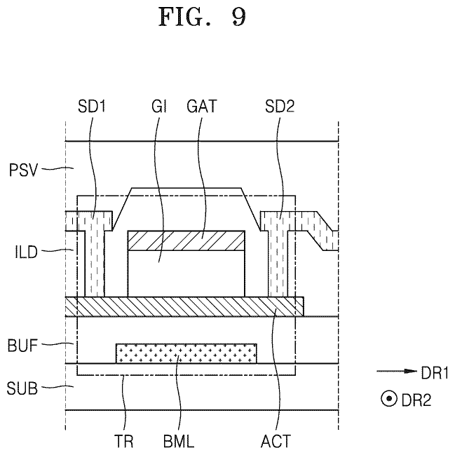

FIG. 9 is a cross-sectional view showing a portion of a pixel circuit according to one or more other embodiments.

The pixel circuit illustrated in FIG. 9 may correspond to the pixel circuit PC3 according to one or more embodiments corresponding to FIG. 6.

Descriptions of configurations of the pixel circuit of FIG. 9 that are substantially the same as or similar to those of the pixel circuit described with reference to FIG. 8 will be omitted.

Referring to FIG. 9, a pixel circuit PC may include a substrate SUB, a lower gate pattern BML, a buffer layer BUF, an active pattern ACT, a gate-insulating layer GI, an upper gate pattern GAT, an interlayer insulating layer ILD, a first conductive pattern SD1, a second conductive pattern SD2, and a protective layer PSV.

The lower gate pattern BML may be arranged between the substrate SUB and the buffer layer BUF. The lower gate pattern BML may include a metal, such as molybdenum (Mo), titanium (Ti), or the like.

A driving transistor of the pixel circuit may include the active pattern ACT, a portion (e.g., upper gate) of the upper gate pattern GAT overlapping the active pattern ACT, and a portion (e.g., lower gate) of the lower gate pattern BML overlapping the active pattern ACT. For example, the portion (upper gate) of the upper gate pattern GAT may form the first gate terminal of the driving transistor T1 in FIG. 6, and the portion (lower gate) of the lower gate pattern BML may form the second gate terminal of the driving transistor T1 in FIG. 6.

When a pixel circuit includes two types of driving transistors (e.g., a first driving transistor and a second driving transistor), the first driving transistor may include a first active pattern, a first portion (a first upper gate) of the upper gate pattern GAT overlapping the first active pattern, and a first portion (a first lower gate) of the lower gate pattern BML overlapping the first active pattern, and the second driving transistor may include a second active pattern, a second portion (a second upper gate) of the upper gate pattern GAT overlapping the second active pattern, and a second portion (a second lower gate) of the lower gate pattern BML overlapping the second active pattern. The first active pattern and the second active pattern can be arranged in the same layer.

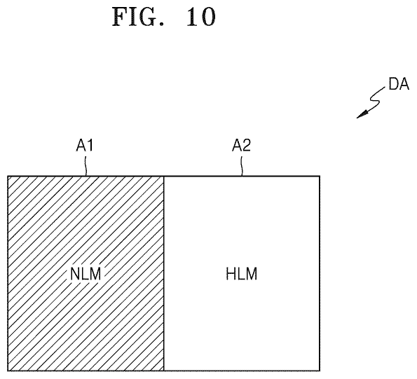

FIG. 10 is a plan view showing a display area according to one or more embodiments.

Referring to FIG. 10, a display area DA may include a first area A1 and a second area A2.

Pixels in the first area A1 may operate in a normal luminance mode NLM or in a low luminance mode LLM (e.g., the first operation mode or the second operation mode), and pixels in the second area A2 may operate in a high luminance mode HLM (e.g., the third operating mode).

The first area A1 and the second area A2 may vary with the state of the display area DA. In one or more embodiments, the second area A2 may include an area of the display area DA, onto which relatively strong external light, such as sunlight, is incident, and the first area A1 may include an area of the display area DA, onto which strong external light is not incident. Accordingly, for the fine grayscale representation in the first area A1, the pixels in the first area A1 may operate in the normal luminance mode NLM or the low luminance mode LLM. For the reduction of power consumption, the pixels in the second area A2 may operate in the high luminance mode HLM.

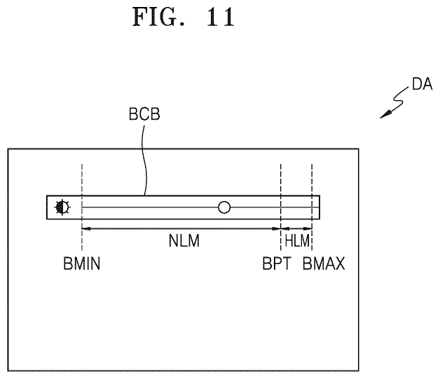

FIG. 11 is a plan view showing a display area according to one or more embodiments.

Referring to FIG. 11, a brightness control bar BCB may be displayed in the display area DA, and a user may control the brightness (luminance) of the display area DA by using the brightness control bar BCB. When a user controls the brightness of the display area DA between a minimum brightness BMIN and a particular brightness (e.g., a selected brightness or a corresponding brightness) BPT, the pixel circuits PC may operate in the normal luminance mode NLM. When a user controls the brightness of the display area DA between the particular brightness BPT and a maximum brightness BMAX, the pixel circuits PC may operate in the high luminance mode HLM.

A pixel circuit or a display device according to various embodiments of the present disclosure may be applied to various electronic devices. According to one or more embodiments, an electronic device includes a pixel circuit or display device, which has been described above, and may further include a module or device, which has additional functions, in addition to the pixel circuit or display device.

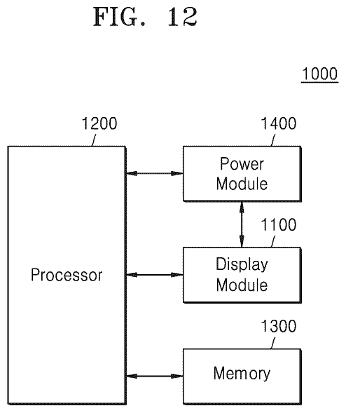

FIG. 12 is a block diagram of an electronic device according to one or more embodiments.

Referring to FIG. 12, the electronic device 1000 may include a display module 1100, a processor 1200, a memory 1300, and a power module 1400.

The processor 1200 may include at least one selected from the group consisting of a central processing unit (CPU), an application processor (AP), a graphics processing unit (GPU), a communication processor (CP), an image signal processor (ISP), and a controller.

Data information necessary for the operation of the processor 1200 or the display module 1100 may be stored in the memory 1300. When the processor 1200 executes an application stored in the memory 1300, an image data signal and/or an input control signal may be transmitted to the display module 1100, and the display module 1100 may process the received signal and output image information through a display screen.

The power module 1400 may include a power supply module, such as a power adapter or a battery device, and a power conversion module that converts power supplied by the power supply module to generate power required for the operation of the electronic device 1000.

At least one of the components of the electronic device 1000 may be included in a display device according to the embodiments described above. Some of the individual modules functionally included in a single module may be included in the display device, and the other individual modules may be provided separately from the display device. For example, the display device may include the display module 1100, and the processor 1200, the memory 1300, and the power module 1400 may be provided in other forms than the form of the display device in the electronic device 1000.

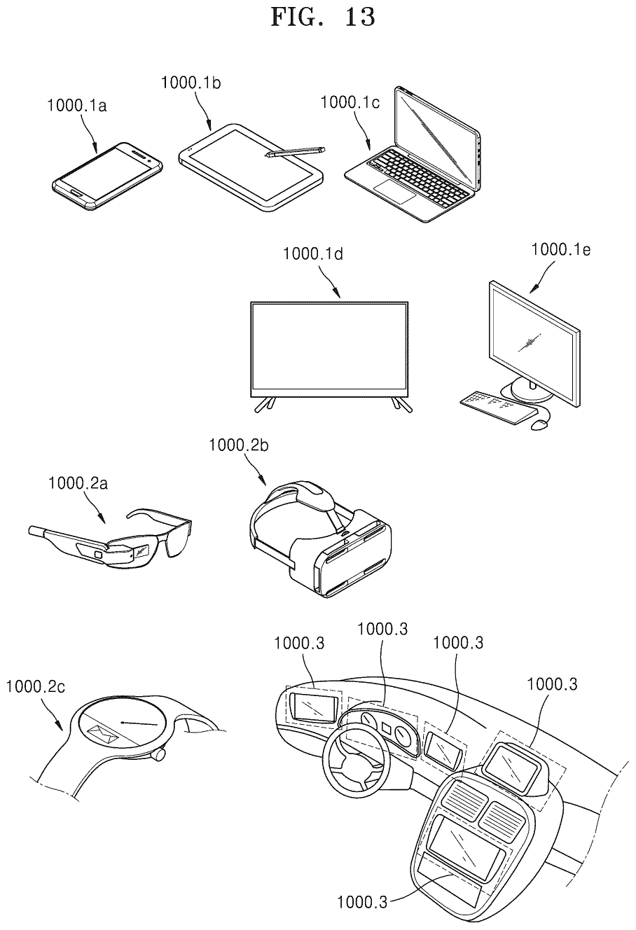

FIG. 13 is a schematic diagram of electronic devices according to various embodiments.

Referring to FIG. 13, various electronic devices to which a display device according to embodiments is applied may include image display electronic devices, such as a smart phone 1000.1a, a tablet personal computer (PC) 1000.1b, a laptop computer 1000.1c, a television (TV) 1000.1d, and a desk monitor 1000.1e, wearable electronic devices, such as smart glasses 1000.2a, a head-mounted display 1000.2b, and a smart watch 1000.2c, each including a display module, and vehicle electronic devices 1000.3, such as a car instrument panel, center fascia, a center information display (CID) arranged on a dashboard, and a room mirror display, each including a display module.

In addition to the embodiments described above, one or more other embodiments of the present disclosure disclose a pixel circuit including a light-emitting element connected between a first power line and a second power line, a first driving transistor connected between the first power line and the light-emitting element, and a second driving transistor connected between the first power line and the light-emitting element, wherein a source terminal of the first driving transistor is connected to a drain terminal of the second driving transistor, and based on a display mode, only the first driving transistor is driven, or both the first driving transistor and the second driving transistor are driven together.

Still one or more other embodiments of the present disclosure disclose a pixel circuit including a light-emitting element connected between a first power line and a second power line, and a driving transistor connected between the first power line and the light-emitting element, the driving transistor including a first gate terminal and a second gate terminal, wherein the driving transistor is controlled to have a source-sync structure or a gate-sync structure based on a display mode. The pixel circuit may further include a switching circuit configured to control the second gate terminal of the driving transistor to be connected to the first gate terminal of the driving transistor or control the second gate terminal of the driving transistor to be connected to a source terminal of the driving transistor, based on the display mode. The switching circuit may include a first switching transistor connected between the first gate terminal of the driving transistor and the second gate terminal of the driving transistor, and a second switching transistor connected between the second gate terminal of the driving transistor and the source terminal of the driving transistor. The pixel circuit may further include a substrate, an active pattern arranged on the substrate and extending in a first direction on a plane, a buffer layer between the substrate and the active pattern, an upper gate pattern arranged on the active pattern, and a lower gate pattern between the substrate and the buffer layer. The driving transistor may include the active pattern, a portion of the upper gate pattern overlapping the active pattern, and a portion of the lower gate pattern overlapping the active pattern.

Yet one or more other embodiments of the present disclosure discloses a display device including a display panel including a plurality of pixel circuits arranged in a display area, and a panel driver configured to drive the display panel, wherein each of the plurality of pixel circuits includes a light-emitting element connected between a first power line and a second power line, a first driving transistor connected between the first power line and the light-emitting element, and a second driving transistor connected between the first power line and the light-emitting element, wherein a source terminal of the first driving transistor is connected to a source terminal of the second driving transistor, a drain terminal of the first driving transistor is connected to a drain terminal of the second driving transistor, and based on a display mode, only the first driving transistor is driven, or both the first driving transistor and the second driving transistor are driven together. The display device may further include a switching circuit configured to turn off the second driving transistor or control a gate terminal of the second driving transistor to be connected to a gate terminal of the first driving transistor, based on the display mode.

One or more additional embodiments of the present disclosure discloses a display device including a display panel including a plurality of pixel circuits arranged in a display area, and a panel driver configured to drive the display panel, wherein each of the plurality of pixel circuits includes a light-emitting element connected between a first power line and a second power line, a first driving transistor connected between the first power line and the light-emitting element, and a second driving transistor connected between the first power line and the light-emitting element, wherein a source terminal of the first driving transistor is connected to a drain terminal of the second driving transistor, and based on a display mode, only the first driving transistor is driven, or both the first driving transistor and the second driving transistor are driven together. The display device may further include a switching circuit configured to control a gate terminal of the first driving transistor to be connected to a gate terminal of the second driving transistor or turn on the second driving transistor, based on the display mode.

One or more other embodiments of the present disclosure disclose a display device including a display panel including a plurality of pixel circuits arranged in a display area, and a panel driver configured to drive the display panel, wherein each of the plurality of pixel circuits includes a light-emitting element connected between a first power line and a second power line, and a driving transistor connected between the first power line and the light-emitting element, the driving transistor including a first gate terminal and a second gate terminal, wherein the driving transistor is controlled to have a source-sync structure or a gate-sync structure based on a display mode. The display device may further include a switching circuit configured to control the second gate terminal of the driving transistor to be connected to the first gate terminal of the driving transistor or control the second gate terminal of the driving transistor to be connected to a source terminal of the driving transistor, based on the display mode.

One or more embodiments of the present disclosure disclose an electronic device including a memory, a processor configured to execute an application stored in the memory, and a display module configured to process a signal transmitted from the processor and output image information, wherein the display module includes a plurality of pixel circuits, wherein each of the plurality of pixel circuits includes a light-emitting element connected between a first power line and a second power line, a first driving transistor connected between the first power line and the light-emitting element, and a second driving transistor connected between the first power line and the light-emitting element, wherein a source terminal of the first driving transistor is connected to a source terminal of the second driving transistor, a drain terminal of the first driving transistor is connected to a drain terminal of the second driving transistor, and based on a display mode, only the first driving transistor is driven, or both the first driving transistor and the second driving transistor are driven together. The electronic device may further include a switching circuit configured to turn off the second driving transistor or control a gate terminal of the second driving transistor to be connected to a gate terminal of the first driving transistor, based on the display mode.

One or more embodiments of the present disclosure disclose an electronic device including a memory, a processor configured to execute an application stored in the memory, and a display module configured to process a signal transmitted from the processor and output image information, wherein the display module includes a plurality of pixel circuits, wherein each of the plurality of pixel circuits includes a light-emitting element connected between a first power line and a second power line, a first driving transistor connected between the first power line and the light-emitting element, and a second driving transistor connected between the first power line and the light-emitting element, wherein a source terminal of the first driving transistor is connected to a drain terminal of the second driving transistor, and based on a display mode, only the first driving transistor is driven, or both the first driving transistor and the second driving transistor are driven together. The electronic device may further include a switching circuit configured to control a gate terminal of the first driving transistor to be connected to a gate terminal of the second driving transistor or turn on the second driving transistor, based on the display mode.

One or more embodiments of the present disclosure disclose an electronic device including a memory, a processor configured to execute an application stored in the memory, and a display module configured to process a signal transmitted from the processor and output image information, wherein the display module includes a display panel including a plurality of pixel circuits arranged in a display area, and a panel driver configured to drive the display panel, wherein each of the plurality of pixel circuits includes a light-emitting element connected between a first power line and a second power line, and a driving transistor connected between the first power line and the light-emitting element, the driving transistor including a first gate terminal and a second gate terminal, wherein the driving transistor is controlled to have a source-sync structure or a gate-sync structure based on a display mode. The electronic device may further include a switching circuit configured to control the second gate terminal of the driving transistor to be connected to the first gate terminal of the driving transistor or control the second gate terminal of the driving transistor to be connected to a source terminal of the driving transistor, based on the display mode.

According to various embodiments of the present disclosure, fine grayscale representation may be realized, and power consumption may be reduced.

The aspects obtainable from the present disclosure are not limited to the aspects mentioned above, and other aspects that have not been mentioned can be clearly understood by one of ordinary skill in the art to which the present disclosure belongs.

Each of the embodiments described above can be implemented independently, but it should be noted that the structure of each embodiment can be applied in combination to other embodiments.

Although the present disclosure has been described with reference to the embodiments shown in the drawings, these are merely examples, and those skilled in the art will understand that various modifications can be made in the embodiments and equivalent other embodiments can be inferred therefrom. Therefore, the technical scope of the present disclosure should be defined by the spirit of the appended claims, with functional equivalents thereof to be included therein.

The implementations described herein are illustrative examples of embodiments, and are not intended to otherwise limit the scope of the embodiments in any way. Moreover, no component is essential to the practice of embodiments unless the component is specifically described as “essential” or “critical.”

The use of any and all examples or language provided herein is intended merely to elaborate embodiments, and does not pose a limitation on the scope of embodiments unless otherwise claimed. Numerous modifications and adaptations will be readily apparent to one of ordinary skill in the art without departing from the spirit and scope of the appended claims or their equivalents.

What is claimed is:

1. A pixel circuit comprising:
a light-emitting element connected between a first power line and a second power line;
a first driving transistor connected between the first power line and the light-emitting element, and comprising a source terminal and a drain terminal; and
a second driving transistor connected between the first power line and the light-emitting element, and comprising a source terminal connected to the source terminal of the first driving transistor, and a drain terminal connected to the drain terminal of the first driving transistor,
wherein, based on a display mode, either only the first driving transistor is driven, or both the first driving transistor and the second driving transistor are driven together.

2. The pixel circuit of claim 1, further comprising a switching circuit configured to either turn off the second driving transistor, or connect a gate terminal of the second driving transistor to a gate terminal of the first driving transistor, based on the display mode.

3. The pixel circuit of claim 2, wherein the switching circuit comprises:
a first switching transistor connected between the gate terminal of the first driving transistor and the gate terminal of the second driving transistor; and
a second switching transistor connected between an off-voltage line and the gate terminal of the second driving transistor.

4. The pixel circuit of claim 1, wherein the drain terminal of the first driving transistor and the drain terminal of the second driving transistor are connected to an anode of the light-emitting element.

5. The pixel circuit of claim 1, further comprising:
a storage capacitor having a first terminal connected to a gate terminal of the first driving transistor, and a second terminal connected to the first power line; and
a scan transistor connected between a data line and the gate terminal of the first driving transistor, and configured to be turned on in response to a scan signal.

6. The pixel circuit of claim 1, further comprising:
a substrate;
a first active pattern above the substrate, and extending in a first direction on a plane;
a second active pattern above the substrate, and extending in the first direction on the plane; and
an upper gate pattern,
wherein the first driving transistor comprises the first active pattern, and a first portion of the upper gate pattern overlapping the first active pattern, and
wherein the second driving transistor comprises the second active pattern, and a second portion of the upper gate pattern overlapping the second active pattern.

7. The pixel circuit of claim 6, wherein a length of the first active pattern in the first direction is different from a length of the second active pattern in the first direction.

8. The pixel circuit of claim 6, wherein a width of the first active pattern in a second direction crossing the first direction is different from a width of the second active pattern in the second direction.

9. A pixel circuit comprising:
a light-emitting element connected between a first power line and a second power line;
a first driving transistor connected between the first power line and the light-emitting element, and comprising a source terminal; and
a second driving transistor connected between the first power line and the light-emitting element, and comprising a drain terminal connected to the source terminal of the first driving transistor,
wherein, based on a display mode, either only the first driving transistor is driven, or both the first driving transistor and the second driving transistor are driven together.

10. The pixel circuit of claim 9, further comprising a switching circuit configured to either connect a gate terminal of the first driving transistor to a gate terminal of the second driving transistor, or turn on the second driving transistor, based on the display mode.

11. The pixel circuit of claim 10, wherein the switching circuit comprises:
a first switching transistor connected between the gate terminal of the first driving transistor and the gate terminal of the second driving transistor; and
a second switching transistor connected between an on-voltage line and the gate terminal of the second driving transistor.

12. The pixel circuit of claim 9, wherein the drain terminal of the second driving transistor is connected to an anode of the light-emitting element.

13. The pixel circuit of claim 9, further comprising:
a storage capacitor having a first terminal connected to a gate terminal of the first driving transistor, and a second terminal connected to the first power line; and
a scan transistor connected between a data line and the gate terminal of the first driving transistor, and configured to be turned on in response to a scan signal.

14. The pixel circuit of claim 9, further comprising:
a substrate;
a first active pattern above the substrate, and extending in a first direction on a plane;
a second active pattern above the substrate, and extending in the first direction on the plane; and
an upper gate pattern,
wherein the first driving transistor comprises the first active pattern, and a first portion of the upper gate pattern overlapping the first active pattern, and
wherein the second driving transistor comprises the second active pattern, and a second portion of the upper gate pattern overlapping the second active pattern.

15. The pixel circuit of claim 14, wherein a length of the first active pattern in the first direction is different from a length of the second active pattern in the first direction.

16. The pixel circuit of claim 14, wherein a width of the first active pattern in a second direction crossing the first direction is different from a width of the second active pattern in the second direction.

17. An electronic device comprising:
a memory;
a processor configured to execute an application stored in the memory; and
a display module configured to process a signal transmitted from the processor, and to output image information, the display module comprising pixel circuits, the pixel circuits comprising:
a light-emitting element connected between a first power line and a second power line; and
a driving transistor connected between the first power line and the light-emitting element, comprising a first gate terminal and a second gate terminal, and configured to be controlled to have a source-sync structure or a gate-sync structure based on a display mode.

18. The electronic device of claim 17, wherein the pixel circuit further comprises a switching circuit configured to control the second gate terminal of the driving transistor to be connected to the first gate terminal of the driving transistor, or to control the second gate terminal of the driving transistor to be connected to a source terminal of the driving transistor, based on the display mode.

19. The electronic device of claim 18, wherein the switching circuit comprises:
a first switching transistor connected between the first gate terminal of the driving transistor and the second gate terminal of the driving transistor; and
a second switching transistor connected between the second gate terminal of the driving transistor and the source terminal of the driving transistor.

20. The electronic device of claim 17, wherein the pixel circuit further comprises:
a substrate;
an active pattern above the substrate, and extending in a first direction on a plane;
a buffer layer between the substrate and the active pattern;
an upper gate pattern above the active pattern; and
a lower gate pattern between the substrate and the buffer layer, and
wherein the driving transistor comprises the active pattern, a portion of the upper gate pattern overlapping the active pattern, and a portion of the lower gate pattern overlapping the active pattern.
